(19) United States
(12) Patent Application Publication
(10) Pub. No.: US 2018/0025926 A1
(43) Pub. Date: Jan. 25, 2018

(54) SUBSTRATE PROCESSING APPARATUS

(71) Applicant: Samsung Electronics Co., Ltd., Suwon-si (KR)

(72) Inventors: HyoJoong Kim, Seongnam-si (KR); Kyungsun Seo, Suwon-si (KR); Jongho Choi, Osan-si (KR)

(21) Appl. No.: 15/650,187

(22) Filed: Jul. 14, 2017

(30) Foreign Application Priority Data
Jul. 19, 2016 (KR) 10-2016-0091537

(51) Int. Cl. H01L 21/67; H01L 21/768; H01L 21/263; H01L 21/677

(52) U.S. Cl. CPC H01L 21/67173; H01L 21/67063; H01L 21/67178; H01L 21/67207; H01L 21/67739; H01L 21/76831; H01L 21/2636

(57) ABSTRACT

A substrate processing apparatus includes an outer tube including an open bottom portion and a closed top portion, and an inner tube disposed in the outer tube and spaced apart from the outer tube. The inner tube includes a first opening at a top portion of the inner tube, a second opening at a bottom portion of the inner tube, and an inner sidewall including a plurality of exhaust holes on one side of the inner sidewall, the inner sidewall defining the first and second openings.

### CROSS-REFERENCE TO RELATED APPLICATIONS

This U.S. non-provisional patent application claims priority under 35 U.S.C §119 of Korean Patent Application 10-2016-0091537, filed on Jul. 19, 2016, the contents of which are hereby incorporated by reference herein in their entirety.

### BACKGROUND

The present inventive concept relates to a substrate processing apparatus.

A substrate processing apparatus may perform a substrate treatment process as a manufacturing process for semiconductor devices. The substrate treatment process may include a thermal diffusion process or a deposition process on the semiconductor device. A general apparatus for processing substrates may carry out the substrate treatment process simultaneously on about 50 to about 100 wafers vertically stacked in a chamber.

### SUMMARY

Embodiments of the present inventive concept provide a substrate processing apparatus capable of enhancing efficiency of a substrate treatment process on wafers.

Embodiments of the present inventive concept provide a substrate processing apparatus capable of efficiently exhausting process gas from an inner tube.

Objects of the present inventive concept are not limited to the above-mentioned objects, as other objects not been mentioned above will be clearly understood to those skilled in the art from the following description.

According to example embodiments of the present inventive concept, a substrate processing apparatus may include: an outer tube including an open bottom portion and a closed top portion; and an inner tube disposed in the outer tube and spaced apart from the inner tube. The inner tube may include: a first opening at a top portion of the inner tube; a second opening at a bottom portion of the inner tube; and an inner sidewall including a plurality of exhaust holes on one side of the inner sidewall, the inner sidewall defining the first and second openings.

According to example embodiments of the present inventive concept, a substrate processing apparatus may include: a chamber that accommodates a boat in which wafers are loaded in a multiple layer arrangement; and a gas exhaust member that produces a pressure in the chamber of 10 Torr or more and exhausts a gas from the chamber. The chamber may include: an inner tube having open top and bottom portions and an inner sidewall including a plurality of exhaust holes; and an outer tube surrounding the top portion and the inner sidewall of the inner tube.

According to example embodiments of the present inventive concept, a substrate processing apparatus may include a chamber and a gas exhaust member. The chamber may include an inner tube and an outer tube. The inner tube may include an inner sidewall, a top opening defined by a top portion of the inner sidewall, a bottom opening defined by a bottom portion of the inner sidewall, and a plurality of exhaust holes defined in one side of the inner sidewall and extending between the bottom portion and the top portion of the inner sidewall. The outer tube may surround the inner sidewall and the top opening of the inner tube. The gas exhaust member may be configured to produce a pressure of 10 Torr or more in the outer tube and may be configured to exhaust a gas from the inner tube through the top opening and the plurality of exhaust holes.

Details of other example embodiments are included in the description and drawings.

### BRIEF DESCRIPTION OF THE DRAWINGS

FIG. 1 is a schematic diagram illustrating a substrate processing apparatus according to example embodiments of the present inventive concept.

FIG. 2 is a perspective view illustrating an inner tube of FIG. 1.

FIG. 3 is a cross-sectional view taken along line I-I′ of FIG. 2.

FIG. 4 is a perspective view illustrating a gas supply member of FIG. 1.

FIGS. 5A and 5B are schematic diagrams illustrating a flow of process gas in a chamber depending on the presence of exhaust holes of FIG. 1.

FIG. 6 is a graph illustrating a flow rate of process gas depending on a height of an inner tube of FIGS. 5A and 5B.

FIG. 7 is a graph illustrating a concentration of reaction gas depending on a height of an inner tube of FIGS. 5A and 5B.

FIG. 8 is a perspective view illustrating another example of an inner tube of FIG. 2.

FIG. 9 is a cross-sectional view taken along line II-II′ of FIG. 8.

FIG. 10 is a plan view illustrating a semiconductor device fabricated using the substrate processing apparatus of FIG. 1.

FIGS. 11A to 11D are cross-sectional views illustrating a substrate treatment process, which is applied to a semiconductor device, using the substrate processing apparatus of FIG. 1.

### DETAILED DESCRIPTION OF EMBODIMENTS

Example embodiments of the present inventive concept are described herein with reference to accompanying drawings.

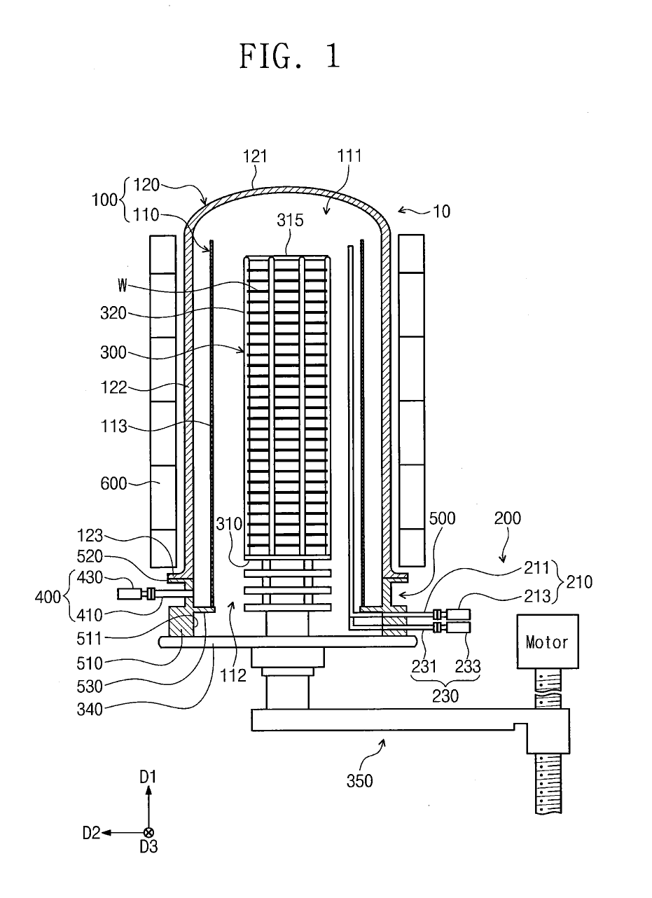

FIG. 1 is a schematic diagram illustrating a substrate processing apparatus according to example embodiments of the present inventive concept.

Referring to FIG. 1, a substrate processing apparatus 10 according to an example embodiment of the present inventive concept may perform a thermal oxidation process and/or a deposition process on one or more wafers W. In some embodiments, the wafers W may include a plurality of semiconductor devices including exposed polysilicon patterns therein or thereon. The polysilicon patterns may include a p-type conductive impurity (referred to hereinafter as an impurity). The substrate processing apparatus 10 may also perform a thermal oxidation process to increase an impurity concentration of the polysilicon patterns. In some embodiments, the impurity may include but is not limited to boron (B).

The substrate processing apparatus 10 may include a chamber 100, a support flange 500, a gas supply member 200, a gas exhaust member 400, a heating member 600, and a boat support member 340. The substrate processing apparatus 10 may further include a boat 300 and a boat driving member 350.

The chamber 100 may provide an inner space where a substrate treatment process is carried out. The substrate treatment process may include a thermal diffusion process, a deposition process, etc. The chamber 100 may include an outer tube 120 and an inner tube 110.

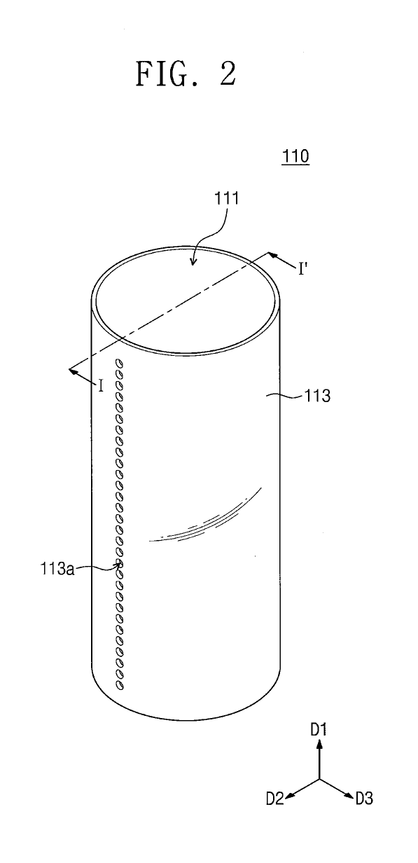

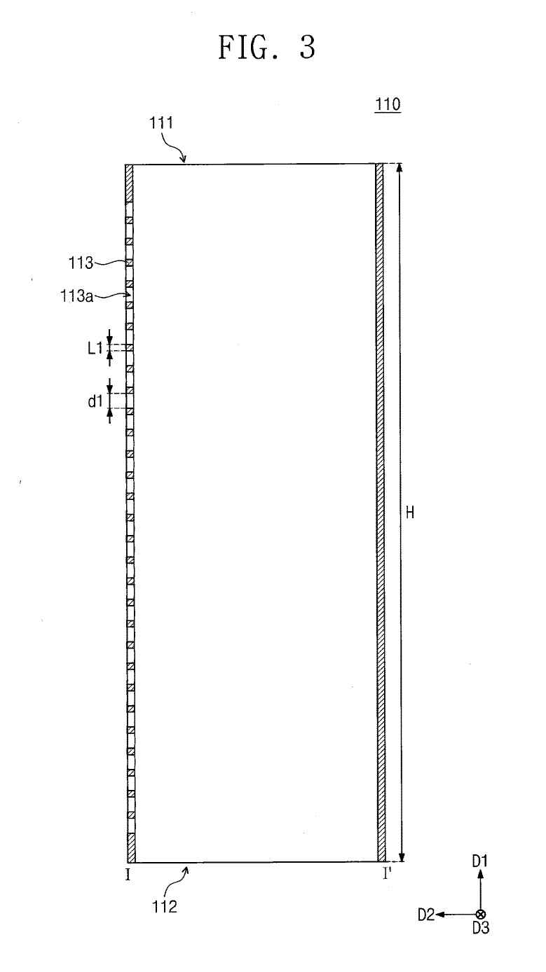

The inner tube 110 may be provided as a barrel or cylindrical shape with its top and bottom open. In this description, an upward direction may mean a first direction D1 and a downward direction may mean a direction inverse or opposite to the first direction D1. The inner tube 110 may include a first opening 111 provided at its top, a second opening 112 provided at its bottom, and an inner sidewall 113 having a plurality of exhaust holes (see 113a of FIG. 2). The inner tube 110 will be discussed in further detail below with reference to FIGS. 2 and 3.

The outer tube 120 may surround an upper portion and the inner sidewall 113 of the inner tube 110. For example, the outer tube 120 may be provided as a cup shape with its bottom open and top closed. The outer tube 120 may include an outer sidewall 122 of an open-bottom barrel or cylindrical shape and a roof 121 of a dome shape. The outer sidewall 122 of the outer tube 120 may be spaced apart at a predetermined distance from the inner sidewall 113 of the inner tube 110. Also, the roof 121 of the outer tube 120 may be spaced apart at a predetermined distance from the first opening 111 of the inner tube 110. Thus, a space may be provided between the outer tube 120 and the inner tube 110.

The outer tube 120 may further include an outer flange 123 extending outwardly from a bottom end of the outer sidewall 122. The outer flange 123 may be provided as a circular ring shape. The outer tube 120 and the inner tube 110 may include but are not limited to quartz.

The support flange 500 may be disposed on a bottom end or side of the chamber 100. The support flange 500 may support the inner and outer tubes 110 and 120. The support flange 500 may include a body 510 provided with a through hole 511 at its center, an outer support portion 520 that supports the outer tube 120, and an inner support portion 530 that supports the inner tube 110.

The through hole 511 of the body 510 may be provided to correspond to or be aligned with a bottom opening of the outer tube 120. For example, the through hole 511 may have a diameter substantially the same as that of the bottom opening of the outer tube 120. The outer support portion 520 may extend outwardly from a top end of the body 510. In some embodiments, the outer support portion 520 may be in contact with or support the outer flange 123 of the outer tube 120. The inner support portion 530 may extend inwardly from the body 510. The inner support portion 530 may be in contact with or support a bottom end of the inner tube 110.

The gas supply member 200 may be connected to a side of the support flange 500. The gas supply member 200 may supply the chamber 100 with a reaction gas, a purge gas, etc. The gas supply member 200 may include a first gas supply portion or section 210 that supplies the reaction gas into the chamber 100 and a second gas supply portion or section 230 that supplies the purge gas into the chamber 100. In some embodiments, the reaction gas may include the impurity and an etching material. In some embodiments, the reaction gas may be BCl₃(g). Alternatively, in other embodiments, the reaction gas may be BF₃(g).

The BCl₃(g) may be decomposed into B⁺ and Cr in the substrate processing apparatus 10. The decomposed B⁺ may be substantially the same as the impurity of the polysilicon pattern. The B⁺ may diffuse into the polysilicon pattern. The impurity concentration of the polysilicon pattern may thus increase. For example, the impurity concentration may increase to a target concentration.

The decomposed Cl⁻ may combine with silicon (Si) of a surface of the polysilicon pattern, thereby forming SiCl₄(g). An upper surface of the polysilicon pattern may be etched. Therefore, the B+ may be the impurity and the CF may be the etching material.

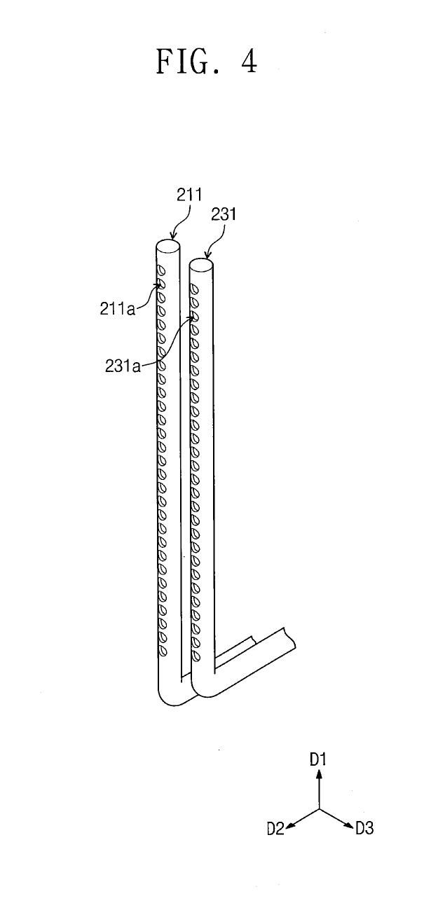

The purge gas may be supplied into the chamber 100 after a thermal diffusion process. The purge gas may purge the reaction gas remaining in the chamber 100. The purge gas may include but is not limited to oxygen (O₂(g)). The first and second gas supply sections 210 and 230 will be discussed in further detail below with reference to FIG. 4.

The gas exhaust member 400 may be connected to an opposite side of the support flange 500 (e.g., an opposite side from the gas supply member 200). In some embodiments, the gas exhaust member 400 may be disposed opposite from the gas supply member 200 in a second direction D2. In other words, the gas exhaust member 400 may be disposed to face the gas supply member 200 across the chamber 100.

The gas exhaust member 400 may exhaust gas from the chamber 100. The gas exhaust member 400 may include a gas exhaust line 410, which is connected to a space between the inner and outer tubes 110 and 120, and a vacuum pump 430, which provides a predetermined pressure into the chamber 100. A pressure may therefore be lower inside the chamber 100 than outside the chamber 100.

The heating member 600 may be disposed outside the outer tube 120. In some embodiments, the heating member 600 may surround the outer flange 123. In some embodiments, the heating member 600 may surround the outer tube 120. The heating member 600 may heat the chamber 100. The heating member 600 may thus keep an inside of the chamber 100 at a process temperature during a substrate treatment process. For example, the heating member 600 may keep the inside of the chamber 100 at a temperature ranging from about 500° C. to about 1000° C.

The boat support member 340 may support the boat 300. The boat support member 340 may be disposed on a bottom end or side of the support flange 500. The boat support member 340 may be provided as a disk shape. When the boat support member 340 is in contact with a bottom end of the support flange 500, the chamber 100 may be hermetically sealed. For example, the boat support member 340 may close the through hole 511 such that the chamber 100 may be hermetically sealed.

The boat driving member 350 may drive to move the boat support member 340 up and down. The boat driving member 350 may also drive to rotate the boat support member 340.

The boat 300 may be disposed on the boat support member 340. The boat driving member 350 may move or put the boat 300 inside the inner tube 110 or outside the chamber 100. A plurality of wafers W may be vertically loaded in the boat 300.

When the boat 300 is positioned in the inner tube 110, a central region of each wafer W may overlap or be in a central region of the inner tube 110. In this description, the central region of the wafer W may mean an area within a certain radius from the center of the wafer W. Also, the central region of the inner tube 110 may mean an area within a certain radius from the central axis of the inner tube 110. In this description, the central axis of the inner tube 110 may be parallel to the first direction D1 and perpendicular to both the second and third directions D2 and D3.

The boat 300 may include an upper plate 315, a lower plate 310, and vertical support columns 320. The upper plate 315 may be spaced apart from the lower plate 310 in the first direction D1. The vertical support columns 320 may connect the upper plate 315 to the lower plate 310. Each of the vertical support columns 320 may include slots into which an edge of the wafer W is inserted. The slots may be arranged at a regular interval or spacing in the first direction D1.

FIG. 2 is a perspective view illustrating the inner tube of FIG. 1. FIG. 3 is a cross-sectional view taken along line I-I′ of FIG. 2.

Referring to FIGS. 2 and 3, the inner tube 110 may be provided as a cylindrical shape with its top and bottom open. The inner tube 110 may have an inner space in which the boat (see 300 of FIG. 1) is disposed. The inner tube 110 may be provided to extend in the first direction D1. For example, the inner tube 110 may have a height H of about 1340 mm. In this description, the height H of the inner tube 110 may mean a vertical length of the inner tube 110.

The first and second openings 111 and 112 of the inner tube 110 may be provided as a circular planar shape. Also, the first and second openings 111 and 112 may have the same diameter. For example, the first and second openings 111 and 112 may each have a diameter of about 363 mm. Alternatively, in other embodiments, the first and second openings 111 and 112 may have different diameters.

The inner sidewall 113 of the inner tube 110 may include, as discussed with reference to FIG. 1, exhaust holes 113a penetrating therethrough. The exhaust holes 113a may be arranged from the first opening 111 toward the second opening 112. For example, the exhaust holes 113a may be vertically arranged along a length direction of the inner tube 110. In some embodiments, the exhaust holes 113a may be arranged in a straight line from the first opening 111 toward the second opening 112, but the present inventive concept is not limited thereto. For example, the exhaust holes 113a may be arranged in a zigzag fashion from the first opening 111 toward the second opening 112 (e.g., the exhaust holes 113a may be staggered).

In some embodiments, the exhaust holes 113a may be arranged spaced apart at a regular interval or spacing L1. For example, the interval L1 of the exhaust holes 113a may be about 7 mm. Alternatively, in other embodiments, the interval may be less for the exhaust holes 113a adjacent the second opening 112 than for the exhaust holes 113a adjacent the first opening 111. For example, the exhaust holes 113a may be arranged at intervals that decrease approaching the second opening 112 from the first opening 111 of the inner tube 110.

The exhaust holes 113a may each have the same diameter d1. For example, the exhaust holes 113a may each have the diameter d1 of about 15 mm. An uppermost one of the exhaust holes 113a may be spaced apart from the first opening 111 of the inner tube 110. Also, a lowermost one of the exhaust holes 113a may be spaced apart from the second opening 112 of the inner tube 110.

FIG. 4 is a perspective view illustrating a gas supply member of FIG. 1.

Referring to FIGS. 1 and 4, the gas supply member 200 may include the first gas supply section 210 and the second gas supply section 230.

The first gas supply section 210 may include a first gas supply line 211 and a first gas tank 213. The first gas tank 213 may hold or reserve the reaction gas. The first gas supply line 211 may be connected to the first gas tank 213. The reaction gas may thus flow within the first gas supply line 211.

The first gas supply line 211 may include a first vertical portion, which is parallel to the inner sidewall 113 of the inner tube 110, and a first interconnecting portion, which connects the first vertical portion to the first gas tank 213. The first vertical portion may be provided elongated in the first direction D1. The first vertical portion may include a plurality of first injecting or injection holes 211a penetrating therethrough. The first injecting holes 211a may be arranged along the first direction D1 in a line such as a straight line. In some embodiments, the first interconnecting portion may extend from a bottom end of the first vertical portion in a direction inverse or opposite to the second direction D2.

The second gas supply section 230 may include a second gas supply line 231 and a second gas tank 233. The second gas tank 233 may hold or reserve the purge gas. The second gas supply line 231 may be connected to the second gas tank 233. The purge gas may thus flow within the second gas supply line 231. The second gas supply line 231 may include a second vertical portion, which is parallel to the inner sidewall 113 of the inner tube 110, and a second interconnecting portion, which connects the second vertical portion to the second gas tank 233. The second vertical portion may be provided elongated in the first direction D1. The second vertical portion may include a plurality of second injecting or injection holes 231a penetrating therethrough. The second injecting holes 231a may be arranged along the first direction D1 in a line such as a straight line. In some embodiments, the second interconnecting portion may extend from a bottom end of the second vertical portion in a direction inverse or opposite to the second direction D2.

The first and second injecting holes 211a and 231a may be arranged at a regular interval or spacing. The first and second gas supply lines 211 and 231 may be spaced apart from each other in the third direction D3. The first and second gas supply lines 211 and 231 may inject the reaction gas and/or the purge gas through the first and second injecting holes 211a and 213a in the second direction D2.

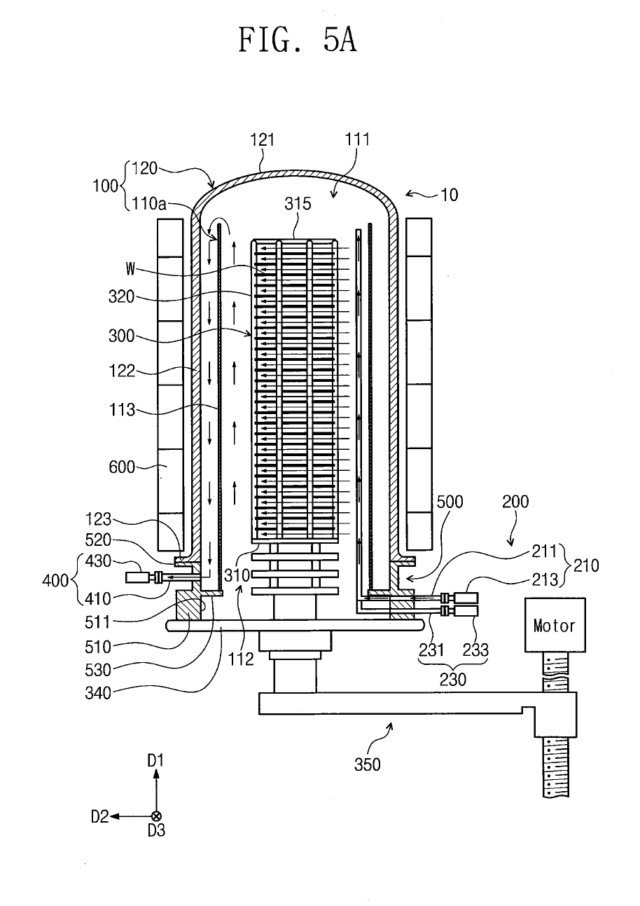

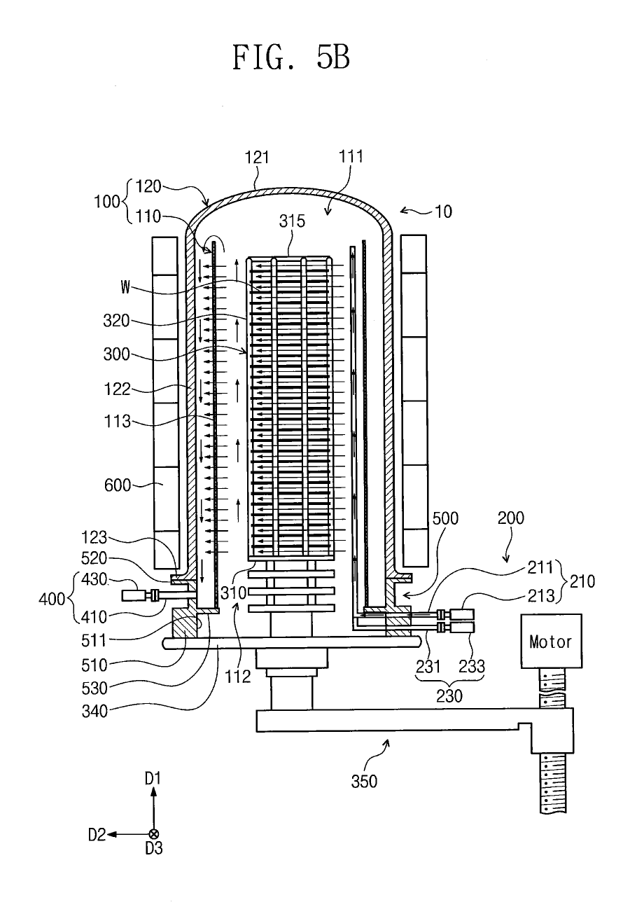

FIGS. 5A and 5B are schematic diagrams illustrating a flow of process gas in a chamber depending on the presence of exhaust holes of FIG. 1. FIG. 5A shows a process gas flow in the chamber 100 in a case that an inner tube 110a does not include the exhaust holes 113a, and FIG. 5B shows a process gas flow in the chamber 100 in a case that the inner tube 110 includes the exhaust holes 113a.

Referring to FIGS. 5A and 5B, the boat 300 is placed in the inner tube 110 (or 110a) and the chamber 100 is hermetically sealed by the boat support member 340, and the gas supply member 200 may inject the reaction gas toward the wafers W loaded in the boat 300. In other words, the first gas supply section 210 may inject the reaction gas in the second direction D2.

The gas exhaust member 400 may keep the chamber 100 under a predetermined pressure. A process gas coming from the inner tube 110 (or 110a) may be exhausted outside the chamber 100 through the gas exhaust member 400. In some embodiments, the pressure in the chamber 100 may be a pressure (e.g., about 50 Torr) less than the atmospheric pressure (e.g., about 760 Torr).

Referring to FIG. 5A, the first gas supply section 210 may inject the reaction gas in the second direction D2 but the inner sidewall 113 may prevent the reaction gas from flowing in the second direction D2. Instead, the reaction gas may flow in the first direction D1 along the inner sidewall 113 of the inner tube 110a. As such, the reaction gas may be exhausted outside the inner tube 110a through the first opening 111.

The influence of pressure of the gas exhaust member 400 may be greater on an edge portion of the inner tube 110a than on a central portion of the inner tube 110a. Therefore, a large amount of the reaction gas may be exhausted outside the inner tube 110a through an edge portion of the first opening 111. In contrast, a small amount of the reaction gas may be exhausted outside the inner tube 110a through a central portion of the first opening 111. In other words, the flow of the reaction gas in the first direction D1 may be greater in the edge portion of the inner tube 110a than in the central portion of the inner tube 110a.

Thus, the impurity concentration of the polysilicon pattern may be larger for the semiconductor devices formed on a central or middle area of the wafer W than for the semiconductor devices formed on an edge area of the wafer W. The impurity concentration of the polysilicon patterns may be non-uniform among the semiconductor devices included in the wafer W.

Referring to FIG. 5B, the gas supply member 200 may inject the reaction gas in the second direction D2. A portion of the reaction gas may be exhausted outside the inner tube 110 through the exhaust holes 113a. The rest of the reaction gas may flow in the first direction D1 and thus may be exhausted outside the inner tube 110 through the first opening 111.

As a portion of the reaction gas is exhausted through the exhaust holes 113a of the inner tube 110, the flow of the reaction gas may be changed. In some embodiments, a large amount of the reaction gas may flow in the central region of the inner tube 110, compared with the case with the inner tube 110a that has no exhaust holes 113a. Therefore, the impurity concentration of the polysilicon patterns may become uniform among the semiconductor devices included in the wafer W, compared with the case with the inner tube 110a that has no exhaust holes 113a.

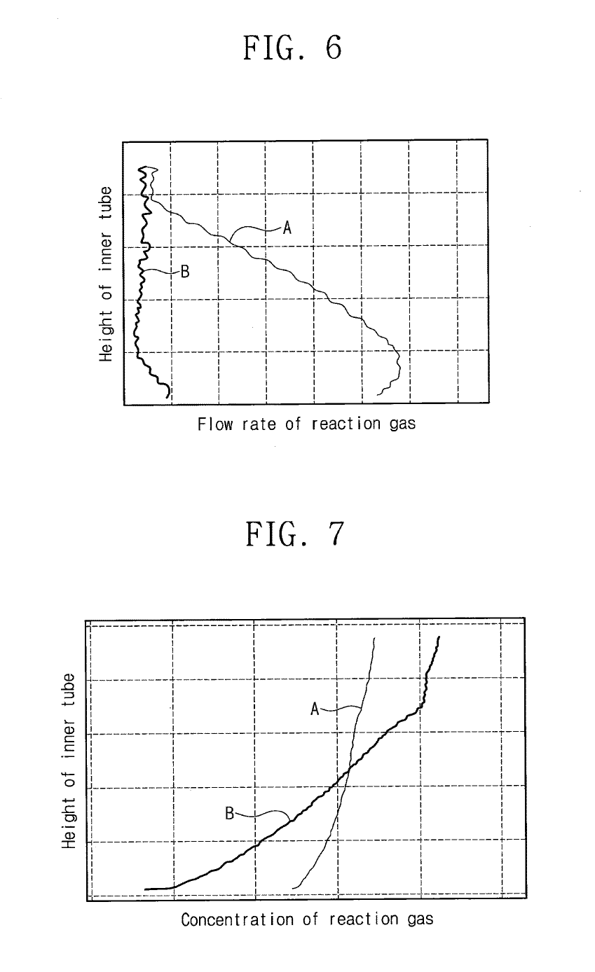

FIG. 6 is a graph illustrating a flow rate of process gas depending on a height of the inner tube of FIGS. 5A and 5B. FIG. 7 is a graph illustrating a concentration of reaction gas depending on a height of the inner tube of FIGS. 5A and 5B. In FIGS. 6 and 7, a thick line B is associated with the case shown in FIG. 5A and a thin line A is associated with the case shown in FIG. 5B. Here, as shown in FIG. 3, the height H of the inner tube 110 may mean a distance in the first direction D1 from the second opening 112 to the first opening 111.

Referring to FIGS. 6 and 7, if the inner tube 110a has no exhaust holes as shown in FIG. 5A, the reaction gas may be exhausted outside the inner tube 110a only through the first opening 111. In this case, the reaction gas of a lower portion of the inner tube 110a may be exhausted more slowly than the reaction gas of an upper portion of the inner tube 110a. That is, the reaction gas of the lower portion of the inner tube 110a may not be efficiently exhausted.

A large amount of Cl⁻ may remain in the lower portion of the inner tube 110a due to the poor exhaustion of the reaction gas. Therefore, a supply amount of the reaction gas may be less for the lower portion of the inner tube 110a than for the upper portion of the inner tube 110a. Namely, a concentration of the reaction gas may be less in the lower portion of the inner tube 110a than in the upper portion of the inner tube 110a.

Due to the poor exhaustion of the reaction gas in the lower portion of the inner tube 110a, a flow rate of the reaction gas may be less in the lower portion of the inner tube 110a than in the upper portion of the inner tube 110a.

A large amount of Cl⁻ may react with B+ as well as silicon (Si) of the polysilicon pattern. In this case, a boron desorption phenomenon may occur on the polysilicon pattern, so that a B+ concentration of the polysilicon pattern may be reduced. The boron desorption phenomenon on the polysilicon pattern may be more intensified in the lower portion of the inner tube 110a than in the upper portion of the inner tube 110a.

However, if the inner tube 110 has the exhaust holes 113a as illustrated in FIG. 5B, the reaction gas may be exhausted outside the inner tube 110 through the first opening 111 and the exhaust holes 113a. In this case, the reaction gas of the lower portion of the inner tube 110 may be efficiently exhausted, compared with the case in which no exhaust holes 113a are provided.

Due to the good exhaustion of the reaction gas in the lower portion of the inner tube 110, an amount of Cl⁻ remaining in the lower portion of the inner tube 110 may be reduced compared with the case in which the inner tube 110a has no exhaust holes. The lower portion of the inner tube 110 may therefore have an increased flow rate of the reaction gas and/or a decreased boron desorption phenomenon of the polysilicon pattern. Moreover, the lower portion of the inner tube 110 may be supplied with an increased amount of the reaction gas. That is, the concentration of the reaction gas may increase.

As the exhaust holes 113a are provided to exhaust a portion of the reaction gas from the lower portion of the inner tube 110, there may be a reduced amount of the reaction gas flowing from the lower portion to the upper portion of the inner tube 110. It may therefore be possible to reduce the concentration of the reaction gas in the upper portion of the inner tube 110, compared with the case in which no exhaust holes 113a are provided.

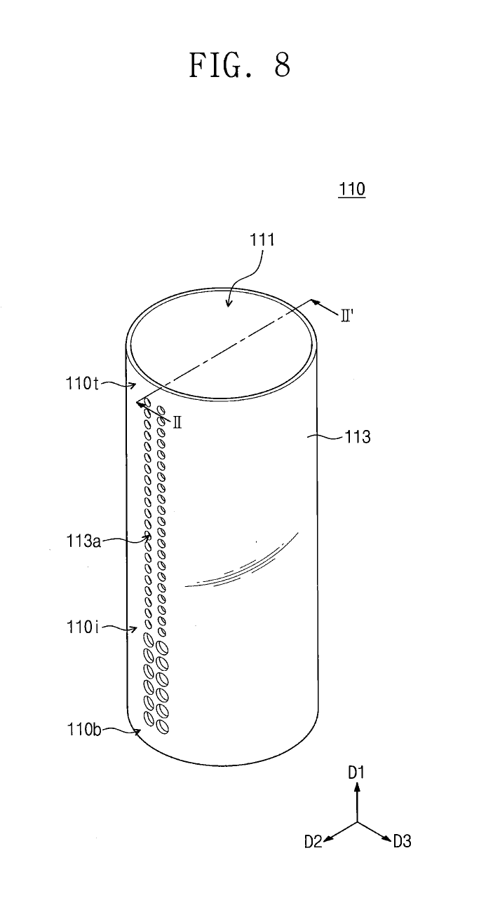

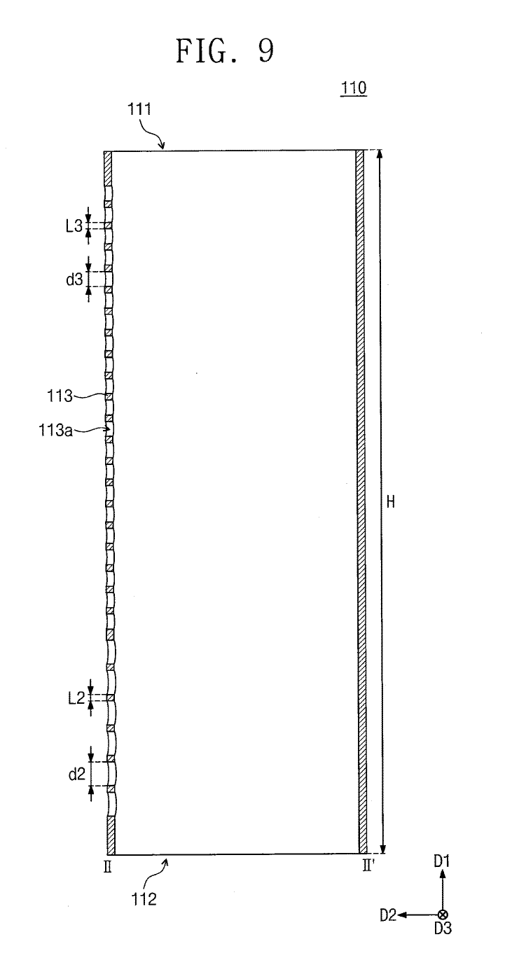

FIG. 8 is a perspective view illustrating another example of the inner tube of FIG. 1. FIG. 9 is a cross-sectional view taken along line II-II′ of FIG. 8. The inner tube 110 illustrated in FIGS. 8 and 9 is similar to the inner tube 110 discussed with reference to FIGS. 2 and 3. For the sake of brevity and simplification, the differences between the configurations will be primarily discussed below.

Referring to FIGS. 8 and 9, the exhaust holes 113a may be arranged in a plurality of lines toward the first opening 111 from the second opening 112 (e.g., between the first and second openings 111 and 112). In some embodiments, the exhaust holes 113a may be arranged in two lines, but the present inventive concept is not limited thereto. The exhaust holes 113a adjacent the second opening 112 may have a diameter d2 greater than a diameter d3 of the exhaust holes 113a adjacent the first opening 111. In this description, the exhaust holes 113a having the diameter d2 may also be referred to hereinafter as lower exhaust holes, and the exhaust holes 113a having the diameter d3 may also be referred to hereinafter as upper exhaust holes. Due to the difference in diameter, an amount of gas exhausted through the lower exhaust holes 113a may be greater than that exhausted from the upper exhaust holes 113a. Alternatively, in another example, the exhaust holes 113a may have diameters that increase or decrease approaching the second opening 112 from the first opening 111.

An interval or spacing L2 between the lower exhaust holes 113a may be less than an interval or spacing L3 between the upper exhaust holes 113a. Therefore, the lower exhaust holes 113a may be arranged more densely than the upper exhaust holes 113a.

In some embodiments, the inner tube 110 (or the inner sidewall 113 thereof) includes a top portion 110t, a bottom portion 110b and an intermediate portion 110i (FIG. 8). At least some of the exhaust holes 113a between the bottom portion 110b and the intermediate portion 110i may have the diameter d2 that is greater than the diameter d3 of at least some of the exhaust holes 113a between the top portion 110t and the intermediate portion 110i. The spacing L2 between adjacent ones of at least some of the exhaust holes 113a between the bottom portion 110b and the intermediate portion 110i may be less than the spacing L3 between adjacent ones of at least some of the exhaust holes 113a between the top portion 110t and the intermediate portion 110i.

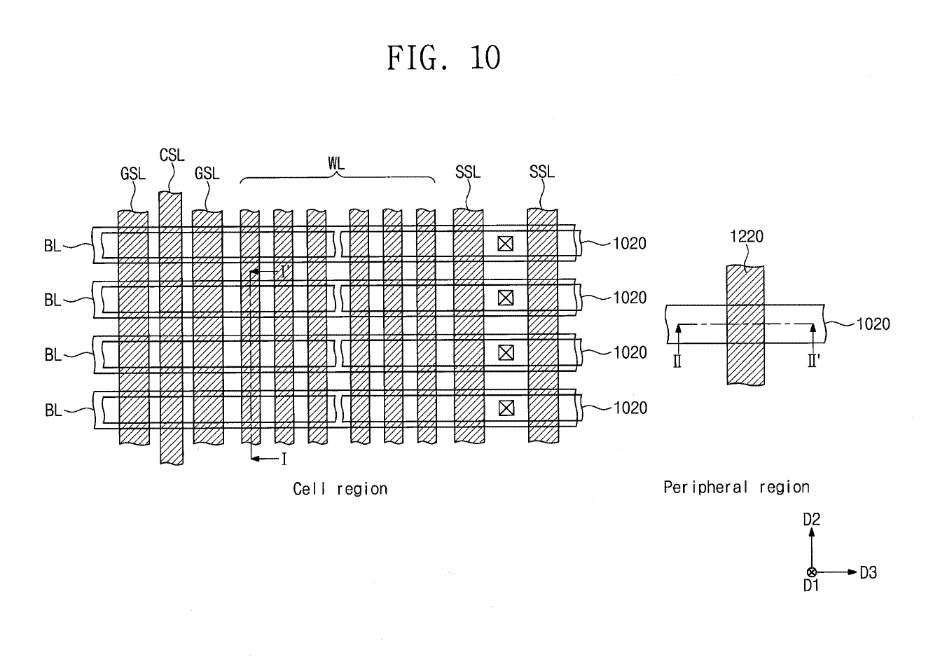

FIG. 10 is a plan view illustrating a semiconductor device fabricated using the substrate processing apparatus of FIG. 1.

Referring to FIG. 10, a semiconductor device according to example embodiments of the present inventive concept may be but is not limited to a NAND flash memory device. The NAND flash memory device may include a memory cell disposed on a cell region of a substrate and a peripheral transistor disposed on a peripheral region of the substrate.

The NAND flash memory device may include a plurality of word lines WL and a plurality of bit lines BL. The word lines WL may extend parallel to each other along a second direction D2.

The NAND flash memory device may include a plurality of memory cells and a plurality of select lines. The select lines may be formed at opposite ends of the memory cells. The select lines may include a string select line SSL and a ground select line GSL. Each of the word lines WL may be formed connected in series to a plurality of memory cells.

A single string may be formed to include the memory cells, which are connected in series between the string select line SSL and the ground select line GSL. The bit lines BL may extend parallel to each other along a third direction D3 different from the extending direction of the word line WL. For example, the word lines WL may extend perpendicular to the bit lines BL. In some embodiments, the second direction D2 may be perpendicular to the third direction D3.

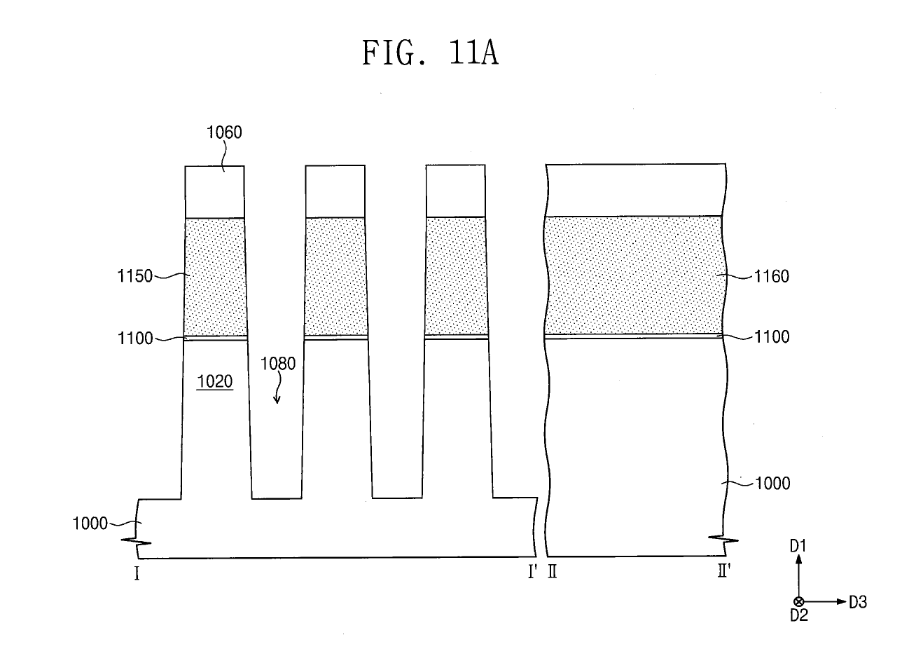

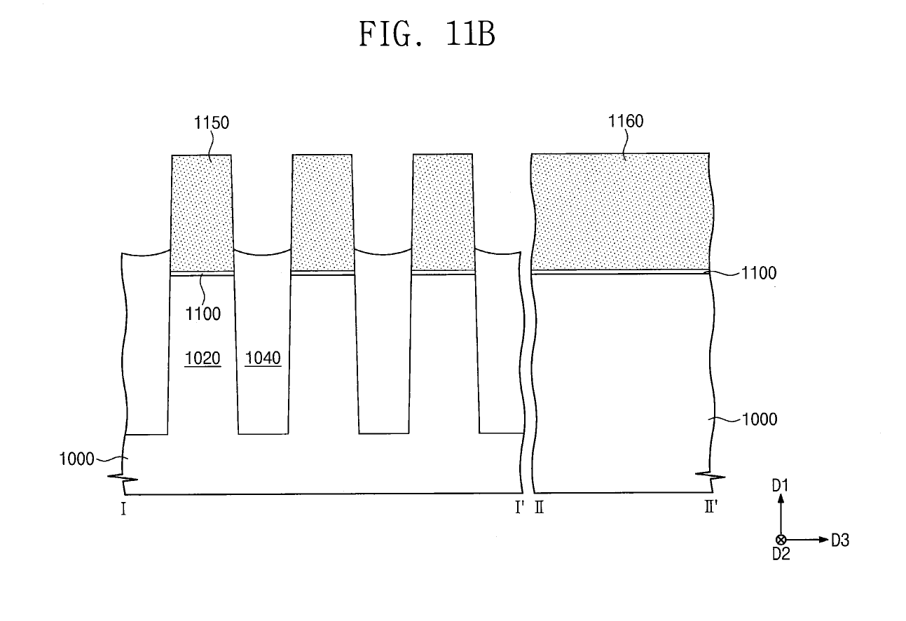

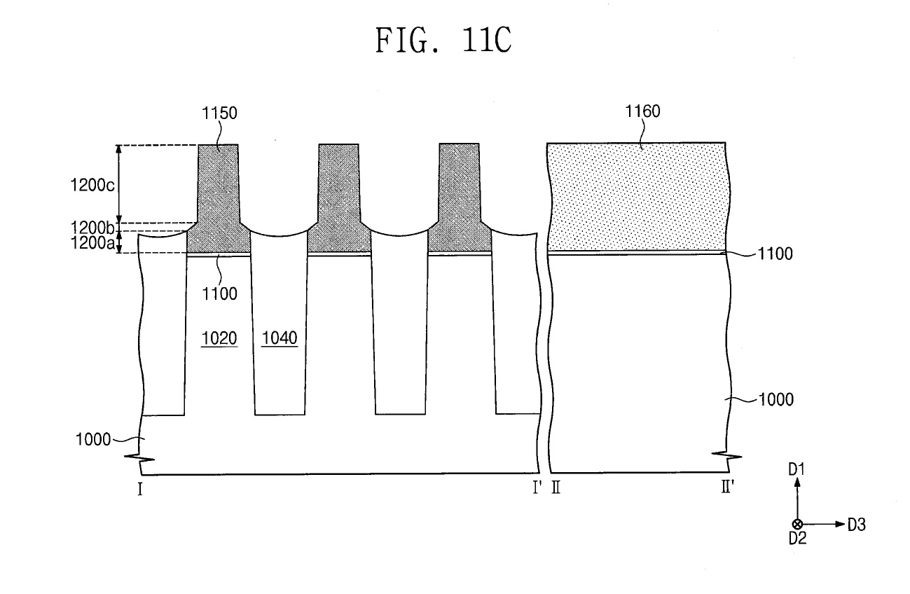

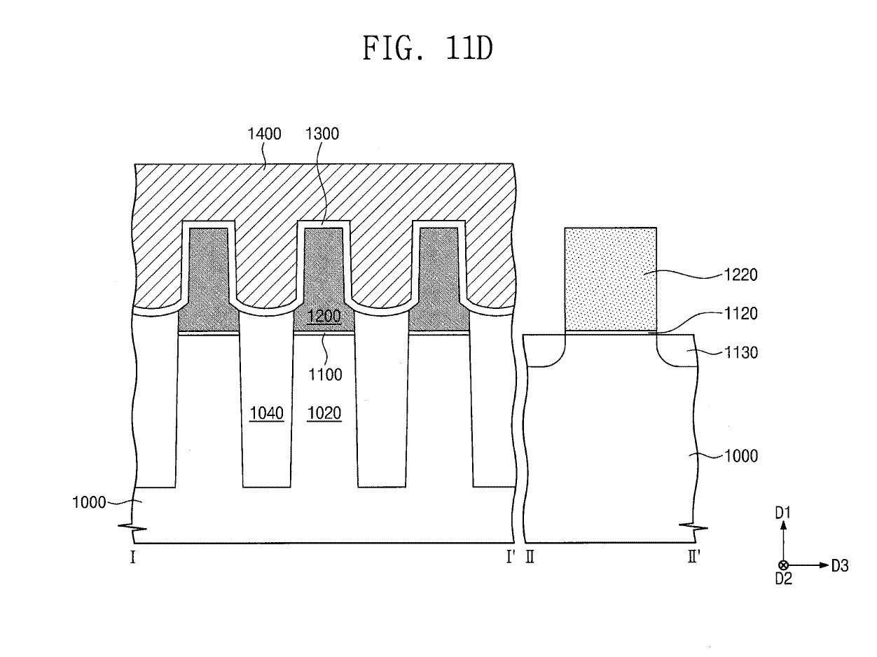

FIGS. 11A to 11D are cross-sectional views illustrating a substrate treatment process, which is applied to a semiconductor device, using the substrate processing apparatus of FIG. 1. FIGS. 11A to 11D show cross-sectional views taken along lines I-I′ and II-II′ of FIG. 10.

Referring to FIG. 11A, a semiconductor device may include a substrate 1000. The semiconductor device may further include an insulation layer 1100, a polysilicon layer, and a mask 1060 that are sequentially stacked on the substrate 1000.

The substrate 1000 may be a semiconductor substrate including silicon (Si) or germanium (Ge), an SOI (Silicon On Insulator) substrate, or a GOI (Germanium On Insulator) substrate.

The insulation layer 1100 may include silicon oxide or metal oxide. A thermal oxidation process or a deposition process may be performed to form the insulation layer 1100 on the substrate 1000.

In some embodiments, the polysilicon layer may be doped with a p-type conductive impurity. For example, the p-type impurity may be boron (B). The polysilicon layer may further include carbon. The polysilicon layer may have a carbon concentration of about 1% to about 10%. The carbon may prevent the boron from being over-diffused.

The mask 1060 may include openings penetrating therethrough. The mask 1060 may include a material having an etch selectivity with respect to the polysilicon layer, the insulation layer 1100, and the substrate 1000. For example, the mask 1060 may include silicon nitride.

The substrate 1000 may undergo an etching process using the mask 1060. In some embodiments, the polysilicon layer may be etched by the etching process using the mask 1060. Through the etching process, a first polysilicon pattern 1150 may be formed on a cell region of the polysilicon layer and a second polysilicon pattern 1160 may be formed on a peripheral region of the polysilicon layer.

The insulation layer 1100 and the substrate 1000 may be etched by an etching process using the mask 1060 and the first polysilicon pattern 1150. Thus, a trench 1080 may be formed to completely penetrate the insulation layer 1100 and partially penetrate the substrate 1000. Active regions 1020 may be formed in the substrate 1000.

Referring to FIG. 11B, the trench 1080 may be filled. A device isolation pattern 1040 may thus be formed to cover a lower portion of the first polysilicon pattern 1150. The device isolation pattern 1040 may be buried within the substrate 1000. The device isolation pattern 1040 may have a downward concave top surface. The device isolation pattern 1040 may include an insulative material having good gap-fill capability. For example, the device isolation pattern 1040 may include HDP (High Density Plasma) oxide. The mask 1060 may be removed.

Referring to FIG. 11C, the first polysilicon pattern 1150 exposed through the device isolation pattern 1040 may experience a thermal diffusion process in the substrate processing apparatus (see 10 of FIG. 1). The reaction gas supplied from the gas supply member 200 may include a p-type conductive impurity and an etching material. In some embodiments, the reaction gas may be but is not limited to BCl₃(g). In other embodiments, the reaction gas may be BF₃(g), etc.

The thermal diffusion process may be performed under a pressure of about 30 Torr or more at a temperature of about 500° C. or more. In some embodiments, the thermal diffusion process may be carried out in the substrate processing apparatus 10 under a pressure of about 50 Torr at a temperature of about 675° C.

When the thermal diffusion process is performed in the substrate processing apparatus 10, the p-type conductive impurity of the reaction gas may diffuse into the first polysilicon pattern 1150 and the etching material of the reaction gas may isotropically etch the exposed first polysilicon pattern 1150. As discussed above, the BCl₃(g) may be decomposed into B⁺ and CF when the thermal diffusion process is performed. The decomposed B⁺ may diffuse into the first polysilicon pattern 1150.

The decomposed Cl⁻ may combine with a silicon (Si) of the surface of the first polysilicon pattern 1150, and thus SiCl₄(g) may be formed. In other words, a top surface of the first polysilicon pattern 1150 may be etched. The discussed thermal treatment on the first polysilicon pattern 1150 may also be executed on the second polysilicon pattern 1160.

After the thermal diffusion process, a purge process may be performed on the substrate 1000 in the substrate processing apparatus 10. The gas supply member 200 of the substrate processing apparatus 10 may supply the purge gas into the chamber 100. The purge process may be performed under temperature and pressure that are less than those required for the thermal diffusion process.

Referring to FIG. 11D, after the purge process, a dielectric layer 1300 may be conformally formed on the first and second polysilicon patterns 1150 and 1160. The dielectric layer 1300 may not completely fill between the first polysilicon patterns 1150 adjacent to each other. The dielectric layer 1300 may be removed from on the second polysilicon pattern 1160, and a conductive layer 1400 may be formed on a remaining dielectric layer 1300. The conductive layer 1400 may include impurity-doped polysilicon, metal, or metal compound.

On the cell region, the conductive layer 1400 and the first polysilicon pattern 1150 may be etched along the second direction (see D2 of FIG. 2) to form a control gate 1400 and a floating gate 1200 that extend along the second direction D2. The dielectric layer 1300 may also be etched along the second direction D2 to have a shape interposed between the control gate 1400 and the floating gate 1200. As a result, on the cell region, a memory cell may be formed to include the insulation layer 1100, the floating gate 1200, the dielectric layer 1300, and the control gate 1400. The insulation layer 1100 and the dielectric layer 1300 may be referred to as a tunnel insulation layer and a blocking insulation layer, respectively.

On the peripheral region, the conductive layer 1400 and the second polysilicon pattern 1160 may be etched to form a gate electrode 1220 consisting of the etched second polysilicon pattern 1160. The insulation layer 1100 may be etched to form a gate dielectric layer 1120 between the gate electrode 1220 and the substrate 1000. Source/drain regions 1130 may be formed on opposite sides of the gate electrode 1220.

According to example embodiments of the present inventive concept, the process gas in the lower portion of the inner tube may be efficiently exhausted. It may be possible to prevent degradation concentrated on the lower portion of the inner tube. A uniform flow amount of the process gas may be achieved throughout central and edge portions of the inner tube. The wafer may thus be provided thereon with the process gas having a uniform concentration.

Effects of the present inventive concept are not limited to the above-mentioned effects, and other effects which have not been mentioned above will be clearly understood to those skilled in the art from the description herein.

Although the present inventive concept has been described in connection with the embodiments of the present inventive concept illustrated in the accompanying drawings, it will be understood by one of ordinary skill in the art that variations in form and detail may be made therein without departing from the spirit and essential features of the inventive concept. The above disclosed embodiments should thus be considered illustrative and not restrictive.

What is claimed is:

1. A substrate processing apparatus, the apparatus comprising:
an outer tube including an open bottom portion and a closed top portion; and
an inner tube disposed in the outer tube and spaced apart from the outer tube,
wherein the inner tube comprises:
a first opening at a top portion of the inner tube;
a second opening at a bottom portion of the inner tube; and
an inner sidewall including a plurality of exhaust holes on one side of the inner sidewall, the inner sidewall defining the first and second openings of the inner tube.

2. The apparatus of claim 1, wherein the exhaust holes are arranged between the second opening and the first opening of the inner tube.

3. The apparatus of claim 2, wherein lowermost ones of the exhaust holes that are adjacent the second opening of the inner tube have a diameter that is greater than a diameter of uppermost ones of the exhaust holes that are adjacent the first opening of the inner tube.

4. The apparatus of claim 2, wherein lowermost ones of the exhaust holes that are adjacent the second opening of the inner tube are spaced apart at an interval that is less than an interval between uppermost ones of the exhaust holes that are adjacent the first opening of the inner tube.

5. The apparatus of claim 1, further comprising a gas exhaust member that is configured to produce a pressure in the outer tube and exhausts a gas from the inner tube through the first opening and the exhaust holes of the inner tube.

6. The apparatus of claim 5, wherein the pressure is in a range of about 10 Torr or more.

7. The apparatus of claim 1, further comprising a gas supply member that is configured to supply a gas to the inner tube.

8. The apparatus of claim 7, wherein the gas supply member comprises a gas supply line disposed in the inner tube, the gas supply line having a plurality of injecting holes facing the exhaust holes of the inner tube.

9. The apparatus of claim 8, wherein the plurality of injecting holes are arranged between the second opening and the first opening of the inner tube.

10. The apparatus of claim 1, further comprising a heating member disposed outside the outer tube and configured to heat the outer tube.

11. A substrate processing apparatus, the apparatus comprising:
a chamber that is configured to accommodate a boat in which wafers are loaded in a multiple layer arrangement; and
a gas exhaust member that produces a pressure in the chamber of 10 Torr or more and exhausts a gas from the chamber,
wherein the chamber comprises:
an inner tube having open top and bottom portions and an inner sidewall including a plurality of exhaust holes; and
an outer tube surrounding the top portion and the inner sidewall of the inner tube.

12. The apparatus of claim 11, wherein the exhaust holes are arranged in a line along a direction from the top portion toward the bottom portion of the inner tube.

13. The apparatus of claim 11, wherein the inner tube has an intermediate portion between the top and bottom portions, and
the exhaust holes between the bottom portion and the intermediate portion of the inner tube have a diameter that is greater than a diameter of the exhaust holes between the top portion and the intermediate portion of the inner tube.

14. The apparatus of claim 11, wherein the inner tube has an intermediate portion between the top and bottom portions, and
adjacent ones of the exhaust holes between the bottom portion and the intermediate portion of the inner tube are spaced apart at an interval that is greater than an interval between adjacent ones of the exhaust holes between the top portion and the intermediate portion of the inner tube.

15. The apparatus of claim 11, further comprising a gas supply member that supplies a gas into the inner tube, the gas supply member including a gas supply line that is disposed in the inner tube and has a plurality of gas injecting holes.

16. A substrate processing apparatus, the apparatus comprising:
a chamber comprising:
an inner tube including:
an inner sidewall;
a top opening defined by a top portion of the inner sidewall;
a bottom opening defined by a bottom portion of the inner sidewall; and
a plurality of exhaust holes defined in one side of the inner sidewall and extending between the bottom portion and the top portion of the inner sidewall; and
an outer tube surrounding the inner sidewall and the top opening of the inner tube; and
a gas exhaust member that is configured to produce a pressure of 10 Torr or more in the outer tube and is configured to exhaust a gas from the inner tube through the top opening and the plurality of exhaust holes.

17. The apparatus of claim 16, wherein the inner sidewall of the inner tube comprises an intermediate portion between the bottom portion and the top portion, and
the exhaust holes between the intermediate portion and the bottom portion of the inner sidewall each have a first diameter,
the exhaust holes between the intermediate portion and the top portion of the inner sidewall each have a second diameter,
the first diameter is larger than the second diameter.

18. The apparatus of claim 16, wherein the inner sidewall of the inner tube comprises an intermediate portion between the bottom portion and the top portion, and
adjacent ones of the exhaust holes between the intermediate portion and the bottom portion of the inner sidewall are spaced apart a first distance,
adjacent ones of the exhaust holes between the intermediate portion and the top portion of the inner sidewall are spaced apart a second distance,
the first distance is smaller than the second distance.

19. The apparatus of claim 16, further comprising a gas supply member extending vertically inside the inner tube, the gas supply member comprising a gas supply line including a plurality of gas injection holes defined therein for supplying a gas into the inner tube.

20. The apparatus of claim 19, wherein the plurality of gas exhaust holes are defined in a first side of the inner sidewall of the inner tube, and
the gas supply line extends vertically adjacent a second side of the inner sidewall of the inner tube that is diametrically opposed from the first side such that the plurality of gas injection holes face the plurality of gas exhaust holes.
